(19) United States
(12) Patent Application Publication
(10) Pub. No.: US 2026/0334169 A1
(43) Pub. Date: Oct. 22, 2026

(54) SEMICONDUCTOR WAFER AND METHOD OF FORMING SEMICONDUCTOR DIE

(71) Applicant: NANYA TECHNOLOGY CORPORATION, New Taipei City (TW)

(72) Inventors: Po-Kai Chang, New Taipei City (TW); Jui Hsiu Jao, New Taipei City (TW)

(73) Assignee: NANYA TECHNOLOGY CORPORATION, New Taipei City (TW)

(21) Appl. No.: 19/180,155

(22) Filed: Apr. 16, 2025

(51) Int. Cl. H10P 74/00; H10P 74/20

(52) U.S. Cl. CPC H10P 74/273; H10P 74/207

(57) ABSTRACT

A semiconductor wafer and a method of forming the semiconductor die are provided. The semiconductor wafer includes a substrate and a test structure. The substrate includes die regions arranged in an array and scribe lines between the die regions. The test structure is disposed on the substrate in the scribe line. The test structure includes a first probe pad and a second probe pad spaced apart from each other. The first probe pad and the second probe pad each includes a first portion, a second portion adjacent to but separated from the first portion and a first test circuit electrically connected between the first probe pad and the second probe pad, wherein one of the first portion and the second portion of the first probe pad is physically and electrically connected to the first test circuit.

### BACKGROUND

### Technical Field

The present invention relates to a semiconductor wafer and a method of forming a semiconductor die, and in particular to a semiconductor wafer with a test structure and a method of forming a semiconductor die from the semiconductor wafer.

### Description of Related Art

A singulation process is often performed after the testing of the wafer is done. One of the singulation process is stealth dicing, which uses a laser beam to focus internally in the semiconductor substrate to form a start point for cracking, and then applies external stress to the wafer to separate the wafer into multiple dies. By stealth dicing, the dicing streets can be minimized and the debris generated during dicing is little. However, a portion of the laser beam may possibly irradiate to the probe pads for the test element groups formed on the scribe line along the laser path, and the probe pad may reflect the laser energy to the semiconductor substrate not located along the laser path which may cause wafer cracking to the unexpected places, such as the die region and thereby lowering the yield.

### SUMMARY

The present invention provides a semiconductor wafer and a method of forming a semiconductor die, which has improved yield.

The semiconductor wafer of the present invention includes a substrate and a test structure. The substrate includes die regions arranged in an array and scribe lines between the die regions. The test structure is disposed on the substrate in the scribe line. The test structure includes a first probe pad and a second probe pad spaced apart from each other. The first probe pad and the second probe pad each includes a first portion, a second portion adjacent to but separated from the first portion and a first test circuit electrically connected between the first probe pad and the second probe pad, wherein one of the first portion and the second portion of the first probe pad is physically and electrically connected to the first test circuit.

In an embodiment of the semiconductor wafer of the present invention, one of the first portion and the second portion of the second probe pad is physically and electrically connected to the first test circuit.

In an embodiment of the semiconductor wafer of the present invention, the scribe line is defined to have a first region and a second region by a laser path for a singulation process, and the first region and the second region are at opposite sides of the laser path. The first portion of the first probe pad and the first portion of the second probe pad are located in the first region, and the second portion of the first probe pad and the second portion of the second probe pad are located in the second region.

In an embodiment of the semiconductor wafer of the present invention, a gap between the first portion and the second portion of the first probe pad and a gap between the first portion and the second portion of the second probe pad are extended along the laser path.

In an embodiment of the semiconductor wafer of the present invention, the test structure further includes a dielectric layer disposed on the substrate, and the first probe pad and the second probe pad are disposed on the dielectric layer. The first test circuit includes upper line segments disposed on the dielectric layer, lower line segments disposed in the dielectric layer and located below the upper line segments, and conductive vias disposed in the dielectric layer and connected between the upper line segments and the lower line segments.

In an embodiment of the semiconductor wafer of the present invention, the upper line segments of the first test circuit are not overlapped with a laser path for a singulation process.

In an embodiment of the semiconductor wafer of the present invention, one of the upper line segments is in direct contact with one of the first portion and the second portion of the first probe pad, and another one of the upper line segments is in direct contact with one of the first portion and the second portion of the second probe pad.

In an embodiment of the semiconductor wafer of the present invention, the one of the upper line segments is located in the second region and in direct contact with the second portion of the first probe pad. The another one of the upper line segments is located in the first region and in direct contact with the first portion of the second probe pad.

In an embodiment of the semiconductor wafer of the present invention, the test structure further includes a third probe pad, a fourth probe pad, and a second test circuit electrically connected between the third probe pad and the fourth probe pad. One of the conductive vias of the first test circuit is shared by the first test circuit and the second test circuit.

In an embodiment of the semiconductor wafer of the present invention, the second test circuit includes a first upper line segment disposed on the dielectric layer and physically connected to the third probe pad, a second upper line segment disposed on the dielectric layer and physically connected to the fourth probe pad, a first lower line segment disposed in the dielectric layer, a first conductive via disposed in the dielectric layer and connected between the first upper line segment and the first lower line segment, and a second conductive via disposed in the dielectric layer and connected between the second upper line segment and the first lower line segment. The second conductive via of the second test circuit is in common with the one of the conductive vias of the first test circuit.

In an embodiment of the semiconductor wafer of the present invention, the first probe pad and the second probe pad are configured to receive and transfer a current from a pair of test probes, and the third probe pad and the fourth probe pad are configured to measure a voltage therebetween by another pair of test probes.

The method of forming a semiconductor die includes the following steps. A semiconductor wafer is provided. The semiconductor wafer includes a substrate and a test structure. The substrate includes die regions arranged in an array and scribe lines between the die regions. The test structure is disposed on a front side of the substrate in the scribe line. The test structure includes a first probe pad and a second probe pad spaced apart from each other. The first probe pad and the second probe pad each includes a first portion, a second portion adjacent to but separated from the first portion and a first test circuit electrically connected between the first probe pad and the second probe pad, wherein one of the first portion and the second portion of the first probe pad is physically and electrically connected to the first test circuit. An electrical test is performed to the test structure. A singulation process is performed to form semiconductor dies.

In an embodiment of the method of forming the semiconductor die of the present invention, the singulation process includes the following steps. A laser beam scanning is performed from a backside of the substrate along a laser path in the scribe lines, wherein the backside is opposite to the front side. An external stress is applied to the semiconductor wafer to separate the semiconductor wafer into the semiconductor dies.

In an embodiment of the method of forming the semiconductor die of the present invention, the laser path is not overlapped the first probe pad and the second probe pad.

In an embodiment of the method of forming the semiconductor die of the present invention, the laser path is extended along a gap between the first portion and the second portion of the first probe pad and a gap between the first portion and the second portion of the second probe pad.

In an embodiment of the method of forming the semiconductor die of the present invention, during performing the laser beam scanning, a modified layer is formed in the substrate, and the modified layer is overlapped with the laser path.

Based on the above, the semiconductor wafer of the present application includes probe pads in the scribe line and each probe pads is not overlapped with the laser path for singulation process. Therefore, during singuration process, the possibility of the laser beam irradiating to the probe pads when the laser beam scanning along the laser path reduces, and therefore the risk of the unexpected wafer cracking lowers and thereby the yield of the semiconductor dies improved.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic top view of a portion of a semiconductor wafer according to an embodiment of the present invention.

FIG. 2 is a schematic top view of an enlargement of a scribe line in the semiconductor wafer according to an embodiment of the present invention.

FIG. 3 is a schematic cross-sectional view along line A-A’ shown in FIG. 2.

FIG. 4 is a schematic cross-sectional view along line B-B’ shown in FIG. 2.

FIG. 5 is a schematic cross-sectional view along line C-C’ shown in FIG. 2.

FIG. 6 and FIG. 7 are schematic cross-sectional views of a method of forming a semiconductor die according to an embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

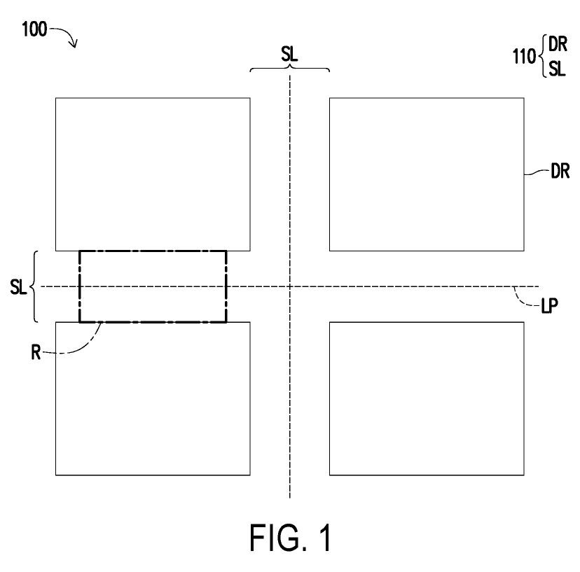

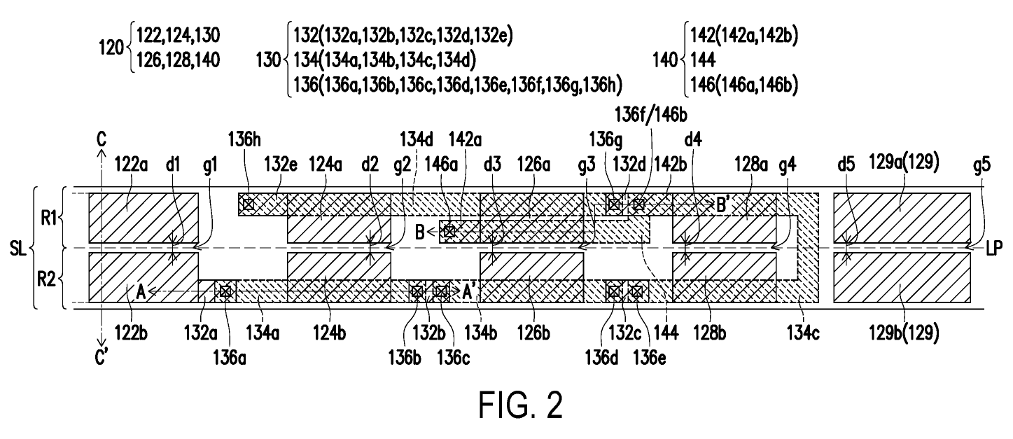

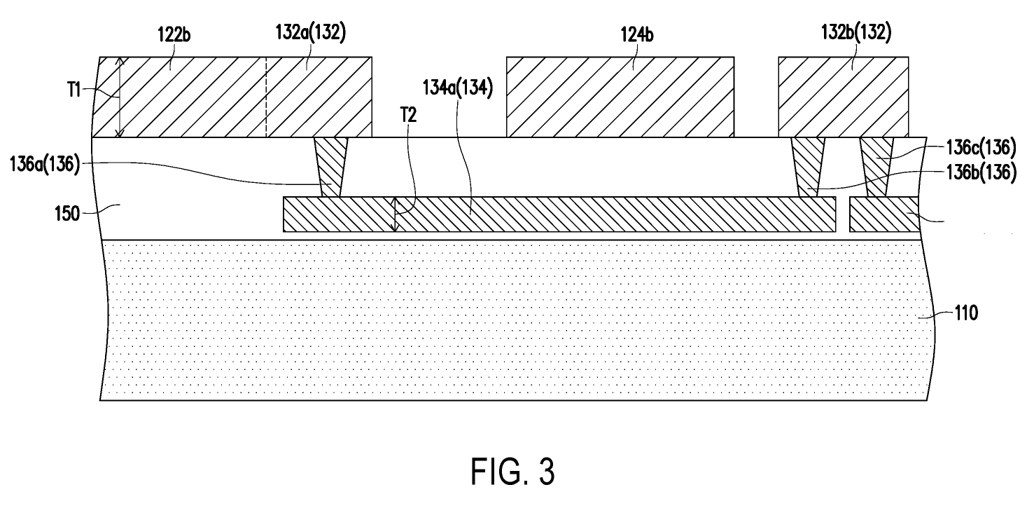

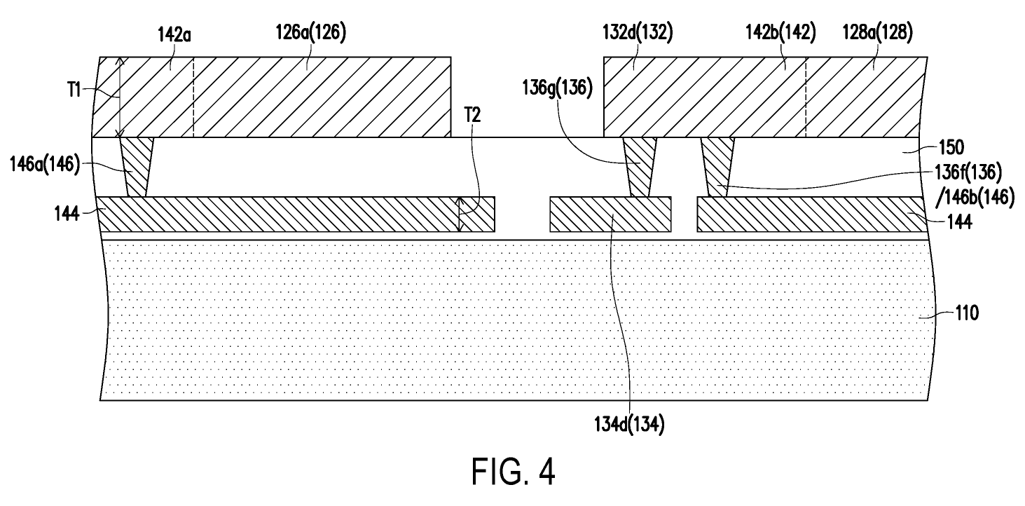

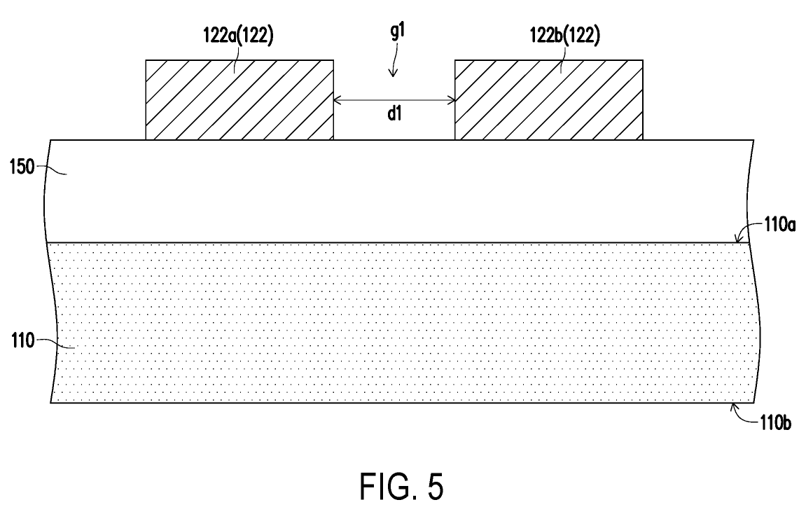

FIG. 1 is a schematic top view of a portion of a semiconductor wafer according to an embodiment of the present invention. FIG. 2 is a schematic top view of an enlargement of a scribe line in the semiconductor wafer according to an embodiment of the present invention. FIG. 3 is a schematic cross-sectional view along line A-A’ shown in FIG. 2. FIG. 4 is a schematic cross-sectional view along line B-B’ shown in FIG. 2. FIG. 5 is a schematic cross-sectional view along line C-C’ shown in FIG. 2. For clarity, FIG. 1 only shows die regions DR and scribe lines SL and other components (such as test structure and etc.) are omitted. FIG. 2 may be an enlargement of a region R shown in FIG. 1 and some components (such as dielectric layer 150 and the substrate 110) are omitted. FIG. 2 is shown in perspective view.

Referring to FIGS. 1 to 5, a semiconductor wafer 100 includes a substrate 110 and a test structure 120. The substrate 110 includes die regions DR arranged in an array and scribe lines SL between the adjacent die regions DR. The test structure 120 is disposed on the substrate 110 in the scribe line SL. The test structure 120 includes a first probe pad 122, a second probe pad 124 and a first test circuit 130 electrically connected between the first probe pad 122 and the second probe pad 124. In some embodiments, the first probe pad 122 and the second probe pad 124 are arranged side by side in the scribe line SL and the second probe pad 124 is spaced apart from the first probe pad 122. In some embodiments, the substrate 110 is a semiconductor substrate. A material of the substrate 110 includes silicon, germanium or other suitable semiconductor materials. There may be devices (not shown) and interconnects (not shown) formed in the die regions DR. In some embodiments, the test structure 120 includes one or more conductive material, for example, metal (such as copper, aluminum, titanium, tungsten, a combination thereof, an alloy thereof or the like), poly-Si or other suitable conductive materials. Although one test structure 120 is shown in FIG. 2, it is appreciated that one or more test structures 120 could be formed in the scribe lines, which is not limited.

The first probe pad 122 and the second probe pad 124 each includes a first portion (such as a first portion 122a of the first probe pad 122 and a first portion 124a of the second probe pad 124 respectively) and a second portion (such as a second portion 122b of the first probe pad 122 and a second portion 124b of the second probe pad 124 respectively). The second portion (such as 122b or 124b) is adjacent to but separated from the first portion (such as 122a or 122b). That is, the first portion and the second portion of the probe pad (such as the first portion 122a and the second portion 122b of the first probe pad 122 or the first portion 124a and the second portion 124b of the second probe pad) are not electrically connected to each other without applying an external component (such as a probe (not shown)).

In some embodiments, the scribe line SL is defined to have a first region R1 and a second region R2 by a laser path LP for a singulation process, and the first region R1 and the second region R2 are at opposite sides of the laser path LP. For example, in FIG. 2, a region of the scribe line SL located above the laser path LP is the first region R1, and a region of the scribe line SL located below the laser path LP is the second region R2. In some embodiments, the first portion 122a of the first probe pad 122 and the first portion 124a of the second probe pad 124 are located in the first region R1, and the second portion 122b of the first probe pad 122 and the second portion 124b of the second probe pad 124 are located in the second region R2. Here, the laser path LP is referred to a scanning path for a laser beam during the singulation process.

In some embodiments, a gap g1 between the first portion 122a and the second portion 122b of the first probe pad 122 and a gap g2 between the first portion 124a and the second portion 124b of the second probe pad 124 are extended along the laser path LP. Therefore, the first probe pad 122 and the second probe pad 124 are not overlapped with the laser path LP, such that it could prevent or reduce the laser beam irradiating to the first probe pad 122 and the second probe pad 124 during subsequent singulation process and resulting in unexpected wafer cracking.

In some embodiments, the test structure 120 further includes a dielectric layer 150 disposed on the substrate 110 as shown in FIG. 3, and the first probe pad 122 and the second probe pad 124 are disposed on the dielectric layer 150.

In some embodiments, the first test circuit 130 includes upper line segments 132 (including 132a, 132b, 132c, 132d and 132e) disposed on the dielectric layer 150, lower line segments 134 (including 134a, 134b, 134c and 134d) disposed in the dielectric layer 150 and located below the upper line segments 132 and conductive vias 136 (including 136a, 136b, 136c, 136d, 136e, 136f, 136g and 136h) disposed in the dielectric layer 150 and connected between the upper line segments 132 and the lower line segments 134. In some embodiments, the upper line segments 132 are located at a same level as the first probe pad 122 and the second probe pad 124. Although FIG. 3 shows only one metallization layer in the dielectric layer 150 for clarity, it is appreciated that there may be multiple metallization layers in the dielectric layer 150 when forming devices or interconnects in the die region DR. In some embodiments, the lower line segments 134 may be any level of metallization layer embedded in the dielectric layer 150, which is not limited.

In some embodiments, the first probe pad 122, the second probe pad 124 and the upper line segments 132 of the first test circuit 130 have substantially the same thickness. In some embodiments, a thickness T1 of the first probe pad 122, the second probe pad 124 or the upper line segments 132 of the first test circuit 130 is greater than a thickness T2 of the lower line segments 134 of the first test circuit 130.

In some embodiments, the upper line segments 132 and the conductive vias 136 of the first test circuit 130 are not overlapped with the laser path LP to prevent or reduce the laser beam irradiating to the upper line segments 132 or the conductive vias 136 during subsequent singulation process and resulting in unexpected wafer cracking. Therefore, each upper line segments 132 and each conductive vias 136 are located in the first region R1 or the second region R2, but not located across the first region R1 and the second region R2. For example, the upper line segments 132a, 132b and 132c as well as the conductive vias 136a, 136b, 136c, 136d and 136e are located in the second region R2, and the upper line segment 132d and 132e as well as the conductive vias 136f, 136g and 136h are located in the first region R1.

In some embodiments, the lower line segments 134 are connected between adjacent upper line segments 132 by corresponding conductive vias 136. For example, the lower line segment 134a in the second region R2 is connected between the upper line segments 132a and 132b by the conductive vias 136a and 136b. The lower line segment 134b in the second region R2 is connected between the upper line segments 132b and 132c by the conductive vias 136c and 136d. The lower line segment 134d in the first region R1 is connected between the upper line segments 132d and 132e by the conductive vias 136g and 136h. The lower line segment 134c is extended from the second region R2 to the first region R1 to connect the upper line segments 132c in the second region R2 and the upper line segment 132d in the first region R1 by the conductive vias 136e and 136f. In this case, the lower line segment 134c may be partially overlapped with the laser path LP. Since the thickness of the lower line segments 134 is small, little of the laser energy is reflected by the overlapped portion of the lower line segment 134c during subsequent singulation process, and thus this would not cause an unexpected crack of wafer.

In some embodiments, one of the upper line segments 132 of the first test circuit 130 is in direct contact with one of the first portion 122a and the second portion 122b of the first probe pad 122, and another one of the upper line segments 132 of the first test circuit 130 is in direct contact with one of the first portion 124a and the second portion 124b of the second probe pad 124. For example, in FIG. 2, the second portion 122b of the first probe pad 122 is in direct contact with the upper line segment 132a of the first test circuit 130, but the first portion 122a of the first probe pad 122 is not in direct contact with the first test circuit 130; and the first portion 124a of the second probe pad 124 is in direct contact with the upper line segment 132e of the first test circuit 130, but the second portion 124b of the second portion 124b is not in direct contact with the first test circuit 130. That is, one of the first portion 122a and the second portion 122b of the first probe pad 122 is physically and electrically connected to the first test circuit 130. The other one of the first portion 122a and the second portion 122b of the first probe pad 122 is not physically connected to the first test circuit 130 and may be electrically connected to the first test circuit 130 through applying an external component (such as a probe) to the first probe pad 122. Besides, one of the first portion 124a and the second portion 124b of the second probe pad 124 is physically and electrically connected to the first test circuit 130. The other one of the first portion 124a and the second portion 124b of the second portion 124b is not physically connected to the first test circuit 130 and may be electrically connected to the first test circuit 130 through applying an external component (such as a probe) to the second probe pad 124.

In some embodiments, the portion of the probe pad (such as the first portion 122a of the first probe pad 122, the second portion 124b of the second probe pad 124 or the like) not physically connected to the first test circuit 130 is configured to enhance the alignment and the conductivity between the probe and the probe pad.

FIG. 2 schematically shows that the first test circuit 130 includes some upper line segments 132, some lower line segments 134 and some conductive vias 136, but the invention is not limited thereto. The number and the layout of upper line segments 132, lower line segments 134 and conductive vias 136 can be adjusted based on the actual requirement. For example, the number and the layout of upper line segments 132, lower line segments 134 and conductive vias 136 may be adjusted based on the designed resistance of the first test circuit 130.

In some embodiments, the test structure 120 further includes a third probe pad 126, a fourth probe pad 128 and a second test circuit 140 electrically connected between the third probe pad 126 and the fourth probe pad 128. In some embodiments, the third probe pad 126 and the fourth probe pad 128 are arranged side by side in the scribe line SL and the third probe pad 126 is spaced apart from the fourth probe pad 128. In FIG. 2, the first probe pad 122, the second probe pad 124, the third probe pad 126 and the fourth probe pad 128 are spaced apart from each other. The second probe pad 124 is located between the first probe pad 122 and the third probe pad 126, and the third probe pad 126 is located between the second probe pad 124 and the fourth probe pad 128.

In some embodiments, similar to the first probe pad 122 and the second probe pad 124, the third probe pad 126 and the fourth probe pad 128 each includes a first portion (such as a first portion 126a of the third probe pad 126 and a first portion 128a of the fourth probe pad 128 respectively) in the first region R1 and a second portion (such as a second portion 126b of the third probe pad 126 and a second portion 128b of the fourth probe pad 128 respectively) in the second region R2.

In some embodiments, a gap g3 between the first portion 126a and the second portion 126b of the third probe pad 126 and a gap g4 between the first portion 128a and the second portion 128b of the fourth probe pad 128 are extended along the laser path LP. Therefore, the third probe pad 126 and the fourth probe pad 128 are not overlapped with the laser path LP, such that it could prevent or reduce the laser beam irradiating to the third probe pad 126 and the fourth probe pad 128 during subsequent singulation process and resulting in unexpected wafer cracking.

In some embodiments, the second test circuit 140 includes upper line segments 142 (including 142a and 142b) disposed on the dielectric layer 150, a lower line segment 144 disposed in the dielectric layer 150 and located below the upper line segments 142 and conductive vias 146 (including 146a and 146b) disposed in the dielectric layer 150 and connected between the upper line segments 142 and the lower line segment 144. For example, the conductive via 146a is connected between the upper line segment 142a and the lower line segment 144, and the conductive via 146b is connected between the upper line segment 142b and the lower line segment 144.

FIG. 2 schematically shows that the second test circuit 130 includes some upper line segments 142, lower line segment 144 and some conductive vias 146, but the invention is not limited thereto. The number and the layout of upper line segments 142, lower line segments 144 and conductive vias 146 can be adjusted based on the actual requirement. For example, the number and the layout of upper line segments 142, lower line segments 144 and conductive vias 146 may be adjusted based on the designed resistance of the second test circuit 140.

In some embodiments, the third probe pad 126, the fourth probe pad 128 and the upper line segments 142 have substantially the same thickness T1 as that of the first probe pad 122, the second probe pad 124 and the upper line segments 132 of the first test circuit 130 and are located at a same level as the first probe pad 122, the second probe pad 124 and the upper line segments 132 of the first test circuit 130. The lower line segment 144 has substantially the same thickness T2 as that of the lower line segments 134 of the first test circuit 130 and is located at a same level as the lower line segments 134 of the first test circuit 130.

In some embodiments, the upper line segments 142 and the conductive vias 146 of the second test circuit 140 are not overlapped with the laser path LP to prevent or reduce the laser beam irradiating to the upper line segments 142 or the conductive vias 146 during subsequent singulation process and resulting in unexpected wafer cracking. Therefore, each upper line segments 142 and each conductive vias 146 are located in the first region R1 or the second region R2, but not located across the first region R1 and the second region R2. For example, the upper line segments 142a and 142b as well as the conductive vias 146a and 146b are located in the first region R1.

In some embodiments, the lower line segment 144 in the first region R1 is connected between the upper line segments 142a and 142b by the conductive vias 146a and 146b. The upper line segment 142a of the second test circuit 140 is in direct contact with the first portion 126a of the third probe pad 126, but the second portion 126b of the third probe pad 126 is not in direct contact with the second test circuit 140. The upper line segment 142b of the second test circuit 140 is in direct contact with the first portion 128a of the fourth probe pad 128, but the second portion 128b of the fourth probe pad 128 is not in direct contact with the fourth test circuit 140. That is, one of the first portion 126a and the second portion 126b of the third probe pad 126 is physically and electrically connected to the second test circuit 140. The other one of the first portion 126a and the second portion 126b of the third probe pad 126 is not physically connected to the second test circuit 140 and may be electrically connected to the second test circuit 140 through applying an external component (such as a probe) to the third probe pad 126. Besides, one of the first portion 128a and the second portion 128b of the fourth probe pad 128 is physically and electrically connected to the second test circuit 140. The other one of the first portion 128a and the second portion 128b of the fourth probe pad 128 is not physically connected to the second test circuit 140 and may be electrically connected to the second test circuit 140 through applying an external component (such as a probe) to the fourth probe pad 128.

In some embodiments, the portion of the probe pad (such as the second portion 126b of the third probe pad 126, the second portion 128b of the fourth probe pad 128 or the like) not physically connected to the second test circuit 140 is configured to enhance the alignment and the conductivity between the probe and the probe pad.

In some embodiments, the upper line segment 132a is located between the first probe pad 122 and the second probe pad 124 in the second region R2. The upper line segment 132b is located between the second probe pad 124 and the third probe pad 126 in the second region R2. The upper line segment 132c is located between the third probe pad 126 and the fourth probe pad 128 in the second region R2. The upper line segment 132d and the upper line segment 142b are located between the third probe pad 126 and the fourth probe pad 128 in the first region R1.

In some embodiments, an orthogonal projection of the lower line segment 134a on the substrate 110 is overlapped with an orthogonal projection of the second portion 124b of the second probe pad 124b on the substrate 110, an orthogonal projection of conductive via 136a on the substrate 110, an orthogonal projection of conductive via 136b on the substrate 110, a portion of an orthogonal projection of the upper line segment 132a on the substrate 110, and a portion of an orthogonal projection of the upper line segment 132b on the substrate 110.

In some embodiments, an orthogonal projection of the lower line segment 134b on the substrate 110 is overlapped with an orthogonal projection of the second portion 126b of the third probe pad 126 on the substrate 110, an orthogonal projection of conductive via 136c on the substrate 110, an orthogonal projection of conductive via 136d on the substrate 110, a portion of an orthogonal projection of the upper line segment 132b on the substrate 110, and a portion of an orthogonal projection of the upper line segment 132c on the substrate 110.

In some embodiments, an orthogonal projection of the lower line segment 134c on the substrate 110 is overlapped with an orthogonal projection of the second portion 128b of the fourth probe pad 128 on the substrate 110, an orthogonal projection of the first portion 128a of the fourth probe pad 128 on the substrate 110, an orthogonal projection of conductive via 136e on the substrate 110, an orthogonal projection of conductive via 136f on the substrate 110, a portion of an orthogonal projection of the upper line segment 132c on the substrate 110, and a portion of an orthogonal projection of the upper line segment 132d on the substrate 110.

In some embodiments, an orthogonal projection of the lower line segment 134d on the substrate 110 is overlapped with an orthogonal projection of the first portion 126a of the third probe pad 126 on the substrate 110, an orthogonal projection of the first portion 124a of the second probe pad 124 on the substrate 110, an orthogonal projection of conductive via 136g on the substrate 110, an orthogonal projection of conductive via 136h on the substrate 110, a portion of an orthogonal projection of the upper line segment 132d on the substrate 110, and an orthogonal projection of the upper line segment 132e on the substrate 110.

In some embodiments, an orthogonal projection of the lower line segment 144 on the substrate 110 is overlapped with an orthogonal projection of the first portion 126a of the third probe pad 126 on the substrate 110, an orthogonal projection of conductive via 146a on the substrate 110, an orthogonal projection of conductive via 146b on the substrate 110, and an orthogonal projection of the upper line segment 142b on the substrate 110.

In some embodiments, the conductive via 146b of the second test circuit 140 and the conductive via 136f of the first test circuit 130 are in common. That is to say, one of the conductive vias 136 of the first test circuit 130 or one of the conductive vias 146 of the second test circuit 140 is shared by the first test circuit 130 and the second test circuit 140. Besides, a portion of the upper line segment 142b of the second test circuit 140 overlapped with the conductive via 146b is shared with the upper line segment 132d of the first test circuit 130, and a portion of the lower line segment 144 of the second test circuit 140 overlapped with the conductive via 146b is shared with the lower line segment 134c of the first test circuit 130. Therefore, the first test circuit 130 may be electrically connected with the second test circuit 140.

In some embodiments, the first probe pad 122 and the second probe pad 124 are configured to transfer a current from a pair of test probes (not shown), so that the current may flow through the first test circuit 130 and the second test circuit 140, and the third probe pad 126 and the fourth probe pad 128 are configured to measure a voltage therebetween by another pair of test probes (not shown). A test element (such as a material or a device to be tested) may be formed at the conductive via 146b, and the electrical property of the test element may be determined by the obtained voltage.

In some embodiments, the semiconductor wafer 100 further includes a dummy probe pad 129 on the substrate 110 in the scribe line SL. The dummy probe pad 129 may be similar to other probe pad and includes a first portion 129a in the first region R1 and a second portion 129b in the second region R2. A gap g5 between the first portion 129a and the second portion 129b is extended along the laser path LP. Therefore, the dummy probe pad 129 is not overlapped with the laser path LP, such that it could prevent or reduce the laser beam irradiating to the dummy probe pad 129 during subsequent singulation process and resulting in unexpected wafer cracking.

In some embodiments, a gap distance (such as d1, d2, d3, d4 and d5) of the gap (g1, g2, g3, g4 and g5) is larger than a laser beam size of the laser beam used for the singulation process, and is smaller than a diameter of a probe head of the probe used for probe testing. In some embodiments, the gas distances d1, d2, d3, d4 and d5 are in a range of 3 μm to 7 μm.

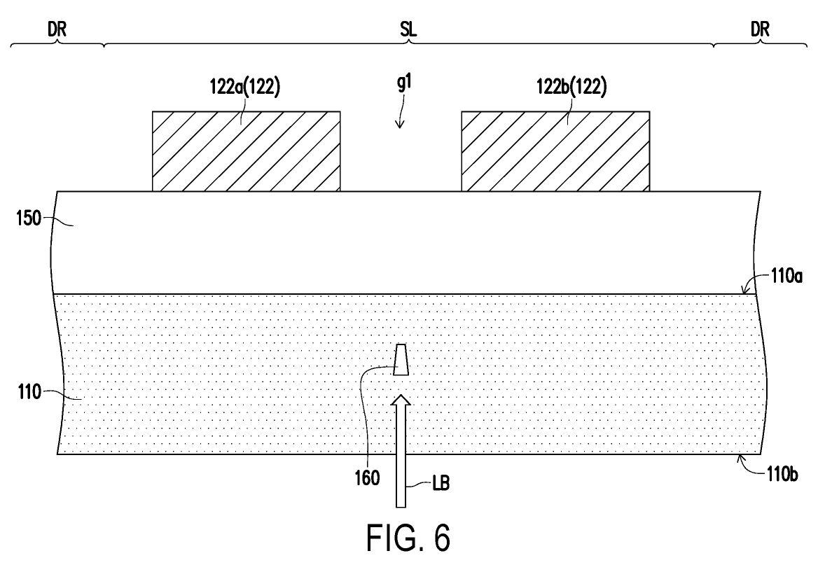

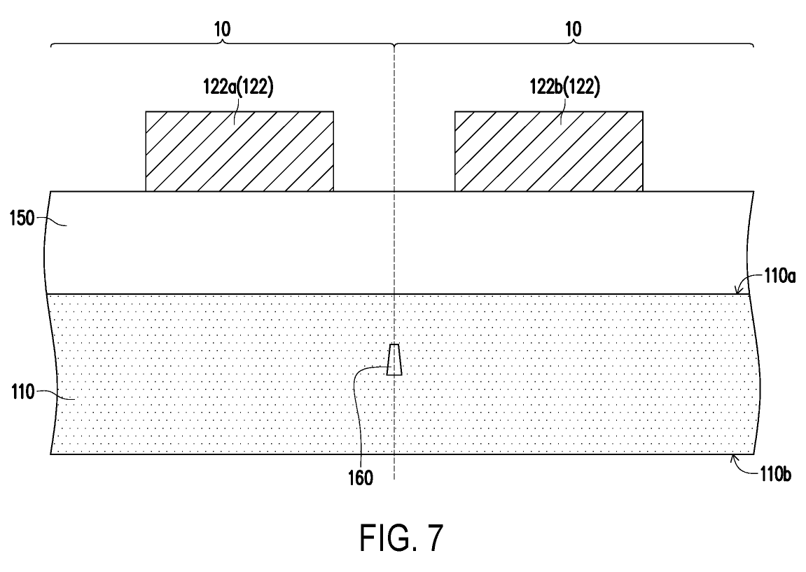

FIG. 6 and FIG. 7 are schematic cross-sectional views of a method of forming a semiconductor die according to an embodiment of the present invention. FIG. 6 and FIG. 7 may be the cross-sectional views along line C-C’ shown in FIG. 2. It must be noted here that the embodiment in FIG. 6 and FIG. 7 continues to use the referential numbers of the elements and a part of the contents of the embodiments of FIG. 1 to FIG. 5, wherein the same or similar referential numbers are used to denote the same or similar elements, and the description of the same technical contents is omitted. For the description of the omitted part, reference may be made to the foregoing embodiments, and details are not repeated here.

Referring to FIG. 6 a semiconductor wafer 100 including a substrate 110 and a test structure 120 is provided. The test structure 120 is formed on a front side 110a of the substrate 110. The semiconductor wafer 100, the substrate 110 and the test structure 120 may be similar to the embodiment described in FIGS. 1 to 4.

Then, an electrical test is performed to the test structure 120. For example, probe heads of a pair of test probes (not shown) contact the first probe pad 122 and the second probe pad 124 (not shown, referring to FIG. 2 for reference) respectively to apply a current to the test structure 120. In the other hand, probe heads of another pair of test probes (not shown) contact the third probe pad 126 and the fourth probe pad 128 (not shown, referring to FIG. 2 for reference) respectively to measure the voltage therebetween to determine if the electrical property of the test element is expected.

Referring to FIG. 6 and FIG. 7, a singulation process is performed to form multiple semiconductor dies 10. For example, in FIG. 6, a laser beam LB scanning is performed from a backside 110b of the substrate 110 along a laser path LP (referring to FIG. 2 for reference) in the scribe lines SL, wherein the backside 110b is opposite to the front side 110a. In some embodiments, during performing the laser beam LB scanning, a modified layer 160 is formed in the substrate 110 to generate internal cracks in the substrate 110, and the modified layer 160 is overlapped with the laser path LP.

Then, in FIG. 7, an external stress is applied to the semiconductor wafer 110 to separate the semiconductor wafer 110 into the semiconductor dies 10. For example, the semiconductor wafer 110 is placed and fixed on a tape (not shown) (such as a dicing tape) and the backside 110b of the semiconductor wafer 110 faces the tape. Then an expansion process is performed to the tape to extend the tape in a peripheral direction so that a stress is applied to the semiconductor wafer 100. The internal cracks in the modified layer 160 may be extended by the stress and thus the semiconductor wafer 100 may be cracked along the modified layer 160 to form multiple semiconductor dies 10.

Since the probe pads (such as the first probe pad 122, the second probe pad 124, the third probe pad 126, the fourth probe pad 128 or the like) in the test structure 120 are formed to have a first portion and a second portion and not overlapped with the laser path LP, the possibility of the laser beam LB irradiating to the probe pads and causing unexpected wafer cracking is lower.

Based on the above, the semiconductor wafer of the present application includes probe pads in the scribe line and each probe pads is not overlapped with the laser path for singulation process. Therefore, during singuration process, the possibility of the laser beam irradiating to the probe pads when the laser beam scanning along the laser path reduces, and therefore the risk of the unexpected wafer cracking lowers and thereby the yield of the semiconductor dies improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor wafer, comprising:
a substrate comprising:
die regions arranged in an array; and
scribe lines between the die regions;
a test structure disposed on the substrate in the scribe line, wherein the test structure comprises:
a first probe pad and a second probe pad spaced apart from each other, wherein the first probe pad and the second probe pad each comprises:
a first portion; and
a second portion adjacent to but separated from the first portion; and
a first test circuit electrically connected between the first probe pad and the second probe pad, wherein one of the first portion and the second portion of the first probe pad is physically and electrically connected to the first test circuit.

2. The semiconductor wafer of claim 1, wherein one of the first portion and the second portion of the second probe pad is physically and electrically connected to the first test circuit.

3. The semiconductor wafer of claim 2, wherein the scribe line is defined to have a first region and a second region by a laser path for a singulation process, and the first region and the second region are at opposite sides of the laser path,
wherein the first portion of the first probe pad and the first portion of the second probe pad are located in the first region, and the second portion of the first probe pad and the second portion of the second probe pad are located in the second region.

4. The semiconductor wafer of claim 3, wherein a gap between the first portion and the second portion of the first probe pad and a gap between the first portion and the second portion of the second probe pad are extended along the laser path.

5. The semiconductor wafer of claim 1, wherein the test structure further comprises a dielectric layer disposed on the substrate, and the first probe pad and the second probe pad are disposed on the dielectric layer,
wherein the first test circuit comprises:
upper line segments disposed on the dielectric layer;
lower line segments disposed in the dielectric layer and located below the upper line segments; and
conductive vias disposed in the dielectric layer and connected between the upper line segments and the lower line segments.

6. The semiconductor wafer of claim 5, wherein the upper line segments of the first test circuit are not overlapped with a laser path for a singulation process.

7. The semiconductor wafer of claim 5, wherein one of the upper line segments is in direct contact with one of the first portion and the second portion of the first probe pad, and
another one of the upper line segments is in direct contact with one of the first portion and the second portion of the second probe pad.

8. The semiconductor wafer of claim 7, wherein the one of the upper line segments is located in the second region and in direct contact with the second portion of the first probe pad, and
wherein the another one of the upper line segments is located in the first region and in direct contact with the first portion of the second probe pad.

9. The semiconductor wafer of claim 5, wherein the test structure further comprises:
a third probe pad and a fourth probe pad; and
a second test circuit electrically connected between the third probe pad and the fourth probe pad,
wherein one of the conductive vias of the first test circuit is shared by the first test circuit and the second test circuit.

10. The semiconductor wafer of claim 9, wherein the second test circuit comprises:
a first upper line segment disposed on the dielectric layer and physically connected to the third probe pad;
a second upper line segment disposed on the dielectric layer and physically connected to the fourth probe pad;
a first lower line segment disposed in the dielectric layer;
a first conductive via disposed in the dielectric layer and connected between the first upper line segment and the first lower line segment; and
a second conductive via disposed in the dielectric layer and connected between the second upper line segment and the first lower line segment,
wherein the second conductive via of the second test circuit is in common with the one of the conductive vias of the first test circuit.

11. The semiconductor wafer of claim 9, wherein the first probe pad and the second probe pad are configured to receive and transfer a current from a pair of test probes, and
the third probe pad and the fourth probe pad are configured to measure a voltage therebetween by another pair of test probes.

12. A method of forming a semiconductor die, comprising:
providing a semiconductor wafer, wherein the semiconductor wafer comprises:
a substrate, wherein the substrate comprises:
die regions arranged in an array; and
scribe lines between the die regions; and
a test structure on a front side of the substrate in the scribe lines, wherein the test structure comprises:
a first probe pad and a second probe pad spaced apart from each other, wherein the first probe pad and the second probe pad each comprises:
a first portion; and
a second portion adjacent to but separated from the first portion; and
a first test circuit electrically connected between the first probe pad and the second probe pad, wherein one of the first portion and the second portion of the first probe pad is physically and electrically connected to the first test circuit;
performing an electrical test to the test structure; and
performing a singulation process to form semiconductor dies.

13. The method of claim 12, wherein the singulation process comprises:
performing a laser beam scanning from a backside of the substrate along a laser path in the scribe lines, wherein the backside is opposite to the front side; and
applying an external stress to the semiconductor wafer to separate the semiconductor wafer into the semiconductor dies.

14. The method of claim 13, wherein the laser path is not overlapped the first probe pad and the second probe pad.

15. The method of claim 13, wherein the laser path is extended along a gap between the first portion and the second portion of the first probe pad and a gap between the first portion and the second portion of the second probe pad.

16. The method of claim 13, wherein during performing the laser beam scanning, a modified layer is formed in the substrate, and the modified layer is overlapped with the laser path.
